(19) United States
(12) Patent Application Publication
(10) Pub. No.: US 2015/0047883 A1
(43) Pub. Date: Feb. 19, 2015

(54) TRANSPARENT CONDUCTIVE COATINGS ON AN ELASTOMERIC SUBSTRATE

(71) Applicant: Cima Nano Tech Israel Ltd., Caesarea (IL)

(72) Inventors: Eyal Shapira, Emek Hefer (IL); Dov Zamir, Beerotaim (IL)

(21) Appl. No.: 14/381,693

(22) PCT Filed: Feb. 28, 2013
(86) PCT No.: PCT/IB13/00820

§ 371 Date: Aug. 28, 2014

Related U.S. Application Data
(60) Provisional application No. 61/604,127, filed on Feb. 28, 2012.

(51) Int. Cl. H05K 1/02; H05K 1/03; H05K 1/09; H01B 13/00

(52) U.S. Cl. CPC H05K 1/0274; H01B 13/0026; H05K 1/0213; H05K 1/0353; H05K 1/09
USPC 174/255; 427/108; 174/250; 174/257

(57) ABSTRACT

A transparent, conductive article that includes a network of electrically conductive metal traces defining cells that are transparent to light on a self-supporting, elastomeric substrate, as well as a process for forming the article.

### CROSS-REFERENCE TO RELATED APPLICATIONS

This application claims priority to U.S. Provisional Application Ser. No. 61/604,127, filed on Feb. 28, 2012. The disclosure of the prior application is considered part of (and is incorporated by reference in) the disclosure of this application.

### TECHNICAL FIELD

This invention relates to preparing transparent conductive articles.

### BACKGROUND

Transparent conductive coatings are useful in a variety of electronics devices. These coatings provide a number of functions such as electromagnetic (EMI shielding) and electrostatic dissipation, and they serve as light transmitting conductive layers and electrodes in a wide variety of applications. Such applications include, but are not limited to, touch screen displays, wireless electronic boards, photovoltaic devices, conductive textiles and fibers, organic light emitting diodes (OLEDs), electroluminescent devices, heaters, and electrophoretic displays, such as e-paper.

Transparent conductive coatings such as those described in U.S. Pat. Nos. 7,566,360 and 7,601,406, and WO2006/135735 are formed from the self-assembly of conductive nanoparticles coated from an emulsion onto a substrate and dried. Following the coating step, the nanoparticles self-assemble into a network-like conductive pattern of randomly-shaped cells that are transparent to light. Typical substrates include non-elastomeric materials such as polyethylene terephthalate or glass.

### SUMMARY

A process is disclosed for forming a transparent conductive coating on an elastomeric substrate. The process includes applying an emulsion to a first substrate to form a wet coating. The emulsion includes metal nanoparticles dispersed in a liquid, where the liquid includes (i) an oil phase comprising a solvent that is non-miscible with water and (ii) a water phase comprising water or a water-miscible solvent. Liquid is evaporated from the coating to form a dry coating that includes a network of electrically conductive metal traces that define cells that are transparent to light. A curable elastomer precursor composition is then deposited over the dry coating and cured to form an elastomeric substrate having a sufficient thickness to be self-supporting. Separating the first substrate and the elastomeric substrate transfers the dry coating from the first substrate to the elastomeric substrate, thereby forming an article comprising a network of electrically conductive metal traces defining cells that are transparent to light on a self-supporting, elastomeric substrate.

The term “nanoparticles” as used herein refers to fine particles small enough to be dispersed in a liquid to the extent they can be coated and form a uniform coating. This definition includes particles having an average particle size less than about three micrometers. For example, in some implementations, the average particle size is less than one micrometer, and in some embodiments the particles measure less than 0.1 micrometer in at least one dimension.

The phrase “transparent to light” generally indicates light transparencies of between 30% and 95% in the wavelength range of about 370 nm to 770 nm.

Implementations of the process may include one or more of the following features. The elastomeric substrate may be a silicone substrate. The cells may be randomly shaped cells. The metal nanoparticles may include silver nanoparticles that create silver traces in the final article. The emulsion may be a water-in-oil emulsion or oil-in-water emulsion. The silicone substrate may have a thickness of at least 0.1 mm, e.g., ranging from 0.1 mm to 10 mm. An example of a suitable siloxane is polydimethylsiloxane. The article may have a transmission of at least 80% to light in the wavelength of 370 nm to 770 nm. The article may exhibit a sheet resistance of no greater than 10 ohms/square, where “sheet resistance” is used as a measure of electrical conductivity. The dry coating may be sintered prior to application of the curable elastomer precursor composition.

Also described are transparent, conductive articles that include a network of electrically conductive metal traces defining cells that are transparent to light on a self-supporting, elastomeric substrate.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is an optical micrograph of a transparent, conductive network on a free-standing, elastomeric, silicone film prepared according to Example 3.

### DETAILED DESCRIPTION

A liquid emulsion containing metal nanoparticles is used to form a transparent conductive layer on a first substrate. The emulsion includes a continuous liquid phase and a dispersed liquid phase that is immiscible with the continuous liquid phase and forms dispersed domains within the continuous liquid phase. In some implementations, the continuous phase evaporates more quickly than the dispersed phase. One example of a suitable emulsion is a water-in-oil emulsion, where water is the dispersed liquid phase and the oil provides the continuous phase. The emulsion can also be in the form of an oil-in-water emulsion, where oil provides the dispersed liquid phase and water provides the continuous phase.

The continuous phase can include an organic solvent. Suitable organic solvents may include petroleum ether, hexanes, heptanes, toluene, benzene, dichloroethane, trichloroethylene, chloroform, dichloromethane, nitromethane, dibromomethane, cyclopentanone, cyclohexanone or any mixture thereof. Preferably, the solvent or solvents used in this continuous phase are characterized by higher volatility than that of the dispersed phase, e.g., the water phase.

Suitable materials for the dispersed liquid phase can include water and/or water miscible solvents such as methanol, ethanol, ethylene glycol, propylene glycol, glycerol, dimethyl formamide, dimethyl acetamide, acetonitrile, dimethyl sulfoxide, N-methyl pyrrolidone.

The emulsion may also contain at least one emulsifying agent, binder or any mixture thereof. Suitable emulsifying agents can include non-ionic and ionic compounds, such as the commercially available surfactants SPAN®-20 (Sigma-Aldrich Co., St. Louis, Mo.), SPAN®-40, SPAN®-60, SPAN®-80 (Sigma-Aldrich Co., St. Louis, Mo.), glyceryl monooleate, sodium dodecylsulfate, or any combination thereof. Examples of suitable binders include modified cellulose, such as ethyl cellulose with a molecular weight of about 100,000 to about 200,000, and modified urea, e.g., the commercially available BYK®-410, BYK®-411, and BYK®-420 resins produced by BYK-Chemie GmbH (Wesel, Germany).

Other additives may also be present in the oil phase and/or the water phase of the emulsion formulation. For example, additives can include, but are not limited to, reactive or non-reactive diluents, oxygen scavengers, hard coat components, inhibitors, stabilizers, colorants, pigments, IR absorbers, surfactants, wetting agents, leveling agents, flow control agents, thixotropic or other rheology modifiers, slip agents, dispersion aids, defoamers, humectants, and corrosion inhibitors. Preferably, however, the emulsions are free of adhesion promoters (i.e., materials that would increase the adhesion of the subsequently formed metal traces to the first substrate).

The metal nanoparticles may be comprised of conductive metals or mixture of metals including metal alloys selected from, but not limited to, the group of silver, gold, platinum, palladium, nickel, cobalt, copper or any combination thereof. Preferred metal nanoparticles include silver, silver-copper alloys, silver palladium or other silver alloys or metals or metals alloys produced by a process known as Metallurgic Chemical Process (MCP) described in U.S. Pat. Nos. 5,476,535 and 7,544,229.

The metal nanoparticles mostly, though not necessarily exclusively, become part of the traces of the conductive network. In addition to the conductive particles mentioned above, the traces may also include other additional conductive materials such as metal oxides (for example ATO or ITO) or conductive polymers, or combinations thereof. These additional conductive materials may be supplied in various forms, for example, but not limited to particles, solution or gelled particles.

Specific examples of suitable emulsions are described in U.S. Pat. No. 7,566,360, which is incorporated by reference in its entirety. These emulsion formulations generally comprise between 40 and 80 percent of an organic solvent or mixture of organic solvents, from 0 to 3 percent of a binder, 0 to 4 percent of an emulsifying agent, 2 to 10 percent of metal powder and 15 to 55 percent of water or water miscible solvent.

Examples of suitable substrates for the first substrate include glass, paper, metal, ceramics, textiles, printed circuit boards, and polymeric films or sheets. The first substrate can be flexible or rigid. Suitable polymeric films can include polyesters, polyamides, polyimides (e.g., Kapton® by Dupont in Wilmington, Del.), polycarbonates, polyethylene, polyethylene products, polypropylene, polyesters such as PET and PEN, acrylate-containing products, polymethyl methacrylates (PMMA), epoxy resins, their copolymers or any combination thereof.

The coating composition can be prepared by mixing all components of the emulsion. The mixture can be homogenized using an ultrasonic treatment, high shear mixing, high speed mixing, or other known methods used for preparation of suspensions and emulsions.

The composition can be coated onto the first substrate using bar spreading, immersing, spin coating, dipping, slot die coating, gravure coating, flexographic plate printing, spray coating, or any other suitable techniques. In some implementations, the homogenized coating composition is coated onto the first substrate until reaching a thickness of about 1 to 200 microns, e.g., 5 to 200 microns.

After applying the emulsion to the first substrate; the liquid portion of the emulsion is evaporated, with or without the application of heat. When the liquid is removed from the emulsion, the nanoparticles self-assemble into a network-like pattern of conductive traces defining cells that are transparent to light.

In some implementations, the cells are randomly shaped. In other implementations, the process is conducted to create cells having a regular pattern. An example of such a process is described in U.S. Ser. No. 61/495,582 entitled “Process for Producing Patterned Coatings,” filed Jun. 10, 2011, which is assigned to the same assignee as the present application and hereby incorporated by reference in its entirety. According to this process, the composition is coated on a surface of the first substrate and dried to remove the liquid carrier while applying an outside force during the coating and/or drying to cause selective growth of the dispersed domains, relative to the continuous phase, in selected regions of the substrate. Application of the outside force causes the non-volatile component (the nanoparticles) to self-assemble and form a coating in the form of a pattern that includes traces defining cells having a regular spacing (for instance, a regular center-to-center spacing), determined by the configuration of the outside force. Application of the outside force may be accomplished, for example, by depositing the composition on the substrate surface and then passing a Mayer rod over the composition. Alternatively, the composition can be applied using a gravure cylinder. In another implementation, the composition may be deposited on the substrate surface, after which a lithographic mask is placed over the composition. In the case of the mask, as the composition dries, the mask forces the composition to adopt a pattern corresponding to the pattern of the mask.

In each case, it is the outside force that governs the pattern (specifically, the center-to-center spacing between cells in the dried coating). However, the width of the traces defining the cells is not directly controlled by of the outside force. Rather, the properties of the emulsion and drying conditions are the primary determinant of the trace width. In this fashion, lines substantially narrower than the outside force can be readily manufactured, without requiring the difficulty and expense of developing processes, masters, and materials having very fine linewidth. Fine linewidth can be generated with the emulsion and drying process. However, the outside force can be used (easily and inexpensively) to control the size, spacing, and orientation of the cells of the network.

Following liquid removal, the coated substrate may be dried and, optionally, sintered to improve conductivity. Sintering may be accomplished by heating, chemical treatment, or a combination thereof. Next, a curable silicone composition is applied over the coated substrate using, e.g., bar spreading, immersing, spin coating, dipping, slot die coating, gravure coating, flexographic plate printing, spray coating, or any other suitable techniques. In some implementations, the curable silicone coating composition is coated onto the first substrate until reaching a wet thickness of about 0.1 to 10 mm. Examples of suitable curable silicone coating compositions include alkyl, aryl, alkylaryl, and fluorosilicones, with polydimethylsiloxane compositions being preferred.

Following coating, the silicone composition is cured, e.g., by heating it to form a crosslinked silicone substrate having a thickness on the order of 0.5 mm to 10 mm. The particular thickness is selected to create an elastomeric silicone substrate that is free-standing (i.e. can be handled without the aid of an additional supporting layer). The crosslinked silicone substrate is then separated/peeled from the first substrate to transfer the dried transparent, conductive coating from the first substrate to the silicone substrate. The resulting elastomeric article is both transparent (e.g., at least 80% transmission of light in the 370 nm to 770 nm wavelength) and conductive (e.g., sheet resistance of no greater than 10 ohms/square). At the same time, it is flexible and substantially retains its initial conductivity when stretched and then allowed to return to its original shape.

### EXAMPLES

### Glossary

| Component | Chemical description | Source |
|---|---|---|
| BYK-410 | Solution of a modified urea | BYK USA, |
| | | Wallingford, CT |
| Span 60 | Sorbitan monostearate | Sigma-Aldrich, St. |
| | | Louis, MO |
| BYK-348 | Silicone surfactant | BYK USA |
| P204 | Silver nanoparticle powder | Cima Nanotech, |
| | prepared as described in | Inc., Israel |
| | U.S. Pat. No. 7,544,229 | |
| Q4-3667 fluid | Silicone polyether (glycol) | Dow Corning, |
| | copolymer | Midland, MI |
| Ethyl cellulose | | Sigma-Aldrich |
| Synperonic NP-30 | Polyethylene glycol | Fluka (Sigma- |
| | nonylphenyl ether | Aldrich) |
| 2AB | 2-amino-1-butanol | Sigma-Aldrich |
| PDMS | Poly[dimethylsiloxane-co-[3- | Sigma-Aldrich |
| | (2-(2-hydroxyethoxy)eth- | |
| | oxy)propyl]methylsiloxane], | |
| | viscosity 75 cSt | |
| U46 PET | Polyethyleneterephthalate | Toray Industries, |
| | film sold under the trade | Inc., Japan |
| | name Lumirror, 100 um | |
| | thickness | |
| SH34 PET | Polyethyleneterephthalate | SKC Inc., South |
| | film sold under the trade | Korea |
| | name Skyrol | |
| Sylgard 184 | Silicone elastomer kit | Dow Corning |
| | (2 parts) | |
| WS001 | Deionized water having | |
| | 0.02 wt % BYK-348 | |

### Test Methods

% Transmission—Measured from 370-770 nm by a Varian Cary 300 Spectrophotometer (Agilent, Santa Clara, Calif.)

Sheet resistance—Measured using a Lutron MO-2002 milliohm meter (Lutron Electronic Enterprise Co., Ltd., Taiwan). Ranges may be reported if multiple points on the same film sample were measured.

Elongation—INSTRON Model 5982 Testing System (Instron, Norwood, Mass.)

Electrical conductance—Keithley Model 236 Source Measure Unit (Keithley, Cleveland, Ohio)

Tables 1 and 2 show premixed compositions that were later combined to make the emulsions shown in Table 3. The dispersions shown in Table 1 were homogenized for 30 sec. using a 200 Watt ultrasonic homogenizer (Bandelin GmbH, Germany) at 90% intensity. Components in Table 2 were combined and mixed until uniform.

TABLE 1
Dispersion compositions (all units are wt %)

| | Example 1 | Example 2 |
|---|---|---|
| BYK-410 | 0.26 | 0.42 |
| Span 60 | 0.21 | 0.24 |
| Cyclohexanone | 7.70 | 7.56 |
| Toluene | 85.034 | 85.61 |
| P204 | 6.79 | 6.03 |
| Aniline | 0 | 0.14 |

TABLE 2
Solution A- Compositions (all units are wt %)

| | |
|---|---|
| Aniline | 4.0 |
| 2AB | 7.9 |
| Synperonic NP-30 | 11.1 |
| Q4-3667 | 22.3 |
| Ethyl cellulose | 54.6 |

TABLE 3
Emulsion compositions (all units are wt %)

| | Example 1 | Example 2 |
|---|---|---|
| Dispersion | 59.99 | 66.94 |
| Solution A | 1.84 | 0 |
| WS001 | 38.17 | 33.06 |

### Example 1

An emulsion was prepared by first mixing together the Dispersion and Solution A using a Bandelin ultrasonic homogenizer at 90% intensity for 30 sec., then adding WS001 to the mixture and homogenizing at 90% intensity for 30 sec., followed by a 1 min. pause, then homogenizing for another 30 sec.

The prepared emulsion was coated onto SH34 PET using a 30 μm Mayer rod and dried under ambient conditions, thus producing a conductive silver network on the PET. The network was then sintered by heating at 150 deg. C. for 3 minutes, then washing for one min. in 1 Molar Hydrochloric acid, then washing for 30 sec. in DI water, then washing for 30 sec. in acetone, then heating again at 150 deg. C. for 2 min. The conductive film was further treated with a 100% plasma for 1 min. (Nanos Low Pressure Plasma System, Diener Electronic, Reading, Pa.).

The two parts of Sylgard 184 silicone were mixed according to manufacturer's directions and the conductive PET was further coated with the silicone using a doctor blade coater, the silicone being applied to the side of the PET having the network. The silicone coated film was cured in an oven for 10 min. at 150 deg. C. to produce a cured silicone film layer laminated to the PET. After cooling, the silicone film was slowly peeled off of the original PET substrate.

A control sample was prepared in a similar manner, but on a PET substrate not having the conductive silver network.

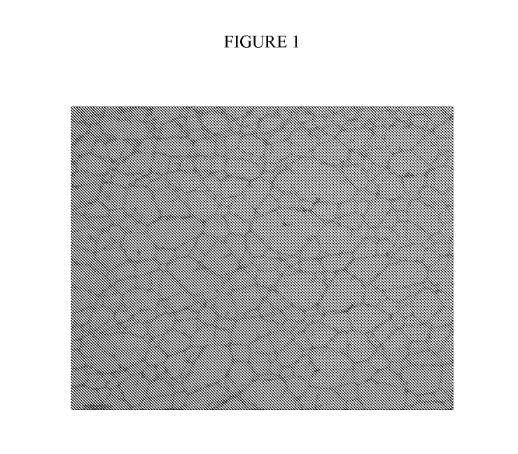

Results: The conductive silver network was completely transferred from the PET to the silicone, producing a conductive network embedded in a free-standing, flexible and elastomeric silicone film having a thickness between 0.6 and 2.0 mm. Transmission and sheet resistance are reported in Table 4. FIG. 1 is a micrograph of the resulting transparent, conductive silicone film.

### Example 2

An emulsion was prepared as described for Example 1, having the composition described in Tables 1-3.

A sheet of U46 PET was primed using a solution of 0.6 wt % Synperonic NP-30 and 0.28 wt % PDMS in acetone. The primer solution was ultrasonically mixed until clear and applied to the PET using a 12 μm Mayer rod and dried for one minute at room temperature.

The prepared emulsion was coated onto the primed PET using a 30 μm Mayer rod and dried at ambient conditions, thus producing a conductive silver network on the PET. The network was then sintered by washing for 1 min. in 1 Molar Hydrochloric acid, followed by washing for 30 sec. in DI water, followed by washing for 30 sec. in acetone, and finally heating at 150 deg. C. for 5 min.

The two parts of Sylgard 184 silicone were mixed according to manufacturer's directions and the conductive PET was further coated with the silicone using a doctor blade coater, the silicone being applied to the side of the PET having the network. The silicone coated film was cured in an oven for 10 min. at 150 deg. C. to produce a cured silicone film layer laminated to the PET. After cooling, the silicone film was slowly peeled off of the original PET substrate.

Results: The conductive silver network was completely transferred from the PET to the silicone, producing a conductive network embedded in a free-standing, flexible, silicone film having a thickness between 0.6 and 2.0 mm. Transmission and sheet resistance are reported in Table 4. A micrograph of the film was similar in appearance to FIG. 1. The surface roughness of the side of the silicone film having the conductive network was measured using a Dektak profilometer (Bruker Corporation, Germany), and a roughness of about 1 um was found. The surface roughness of an area of the same sample without the conductive network was about 60 nm. Thus, the conductive network projected above the surface of the silicone film by about 1 μm.

TABLE 4
Results for Examples 1 and 2

| | | Transmission (%) | Sheet resistance |
|---|---|---|---|
| | Transmission (%) | silicone substrate | (Ohms/square) silicone |
| | silicone substrate | having conductive | having conductive |
| | control | network | network |
| Example 1 | 94.5 | 87.5 | 5 |
| Example 2 | | 84.0 | 4-10 |

### Example 3

Samples were prepared as described for Example 2 with the following addition: the thickness of the silicone film was controlled by constructing molds having varying thicknesses, into which the conductive PET film was placed prior to applying the uncured silicone. Once applied, the uncured silicone was then leveled to be even with the top of the mold.

Results: The conductive silver networks were completely transferred from the PET to the silicone, producing conductive networks embedded in free-standing, flexible, silicone films having varying thicknesses and properties as reported in Table 5.

TABLE 5
Example 3 Results

| Silicone film | Sheet resistance | |
|---|---|---|
| thickness (mm) | (Ohms/square) | Transmission (%) |
| 0.6 | Not measured | 85.2 |
| 1.2 | 3.5-5 | 85.4 |
| 3.0 | Not measured | 84.7 |
| 4.0 | 7.5-9 | 82.2 |
| 5.0 | 3.5-5.5 | 83.3 |
| 6.0 | 8-10 | 83.7 |

### Example 4

A sample was prepared as described in Example 2 having a thickness of 6 mm as described in Example 3. An approximately 2×2 cm piece was cut from the sample and placed in the jaws of an Instron. Two narrow, flat metal tapes were positioned between the Instron jaws and the conductive network side of the silicone film, thus providing contacts to use for electrical conductance testing. The metal contacts were connected with the Keithley meter and electrical conductance was recorded as the Instron jaws were pulled apart, thus elongating the sample. Elongation was stopped at 1.66 mm.

### Results

As can be seen in Table 6, the electrical conductance of the sample decreased by more than two orders of magnitude as the sample was stretched, reaching zero at approximately 8% elongation. Although not shown in Table 6, when the Instron jaws returned the sample to the original, unstretched dimension, the electrical conductance returned to approximately the original value of 0.25 S. This also demonstrated that the silicone film having the conductive silver network could be deformed, i.e. stretched, and then returned to its original unstretched dimension, not undergoing any permanent deformation.

TABLE 6
Example 4 Results

| Elongation (mm) | Elongation (%) | Electrical conductance (Siemens) |
|---|---|---|
| 0 | 0 | 0.25 |
| 0.166 | 0.8 | 0.22 |
| 0.33 | 1.7 | 0.15 |
| 0.49 | 2.5 | 0.092 |
| 0.66 | 3.3 | 0.016 |
| 0.83 | 4.2 | 0.005 |
| 1.00 | 5.0 | 0.005 |
| 1.166 | 5.8 | 0.004 |
| 1.33 | 6.7 | 0.0024 |
| 1.49 | 7.5 | 0.0014 |
| 1.66 | 8.3 | 0.0000 |

### Example 5

A sample was prepared as described in Example 2.

An approximately 2×2 cm piece was cut from the sample. Two narrow, flat metal tapes were attached on opposite ends of the piece such that electrical contact was made with each end of the conductive network. The metal tapes were then connected to a Micro-Ohm Meter (Model 34420A, Agilent Technologies, Santa Clara, Calif.) such that sheet resistances could be measured.

Using clamps to grasp the ends of the sample having the metal tapes, the sample was slowly bent into a U-shape while monitoring the angle of bending and the sheet resistance, then the bending was reversed to the original flat shape. The bending angle was measured at the intersection of two imaginary lines, the lines being co-planar with the surface of the film at the point of clamping, e.g. if the film was flat (not bent) the angle would be 0 degrees, and if the film was bent into a full U-shape, the angle would be 180 degrees. Because only the ends of the film were clamped, the film naturally assumed a curved shape during bending rather than having a sharp V-bend.

Two bending experiments were conducted, one with the conductive network on the concave side of the sample (e.g. on the inside of the U shape, which compressed the network), and one with the conductive network on the convex side of the sample (e.g. on the outside of the U shape, which expanded the network). Results are shown in Table 7 and demonstrate the sheet resistance (ohms/square) during a bending cycle.

TABLE 7

| Bending angle | | Bending angle | |
|---|---|---|---|
| increasing | | decreasing | |
| | Sheet | | Sheet |
| Angle | resistance | Angle | resistance |
| (degrees) | (ohms/sq) | (degrees) | (ohms/sq) |

Network on concave side

| | | | |
|---|---|---|---|
| 20 | 27 | | |
| 43 | 70 | | |
| 62 | 150 | | |
| 63 | 300 | | |
| 68 | 600 | | |
| | | 40 | 30 |
| | | 22 | 50 |
| | | 3 | 65 |

Network on convex side

| | | | |
|---|---|---|---|
| 4 | 27 | | |
| 15 | 50 | | |
| 22 | 90 | | |
| 27 | 100 | | |
| 36 | 151 | | |
| 42 | 250 | | |
| 53 | 730 | | |
| 62 | 1300 | | |
| | | 38 | 54 |
| | | 33 | 33 |
| | | 15 | 25 |
| | | 12 | 22 |

A number of embodiments of the invention have been described. Nevertheless, it will be understood that various modifications may be made without departing from the spirit and scope of the invention. For example, elastomeric substrates other than silicone may be used. For example, suitable substrates include natural and synthetic rubbers. Representative examples include polyacrylic rubbers, fluoroelastomers, perfluoroelastomers, nitrile rubbers, polybutadiene rubbers, and styrene-butadiene rubbers. In addition, other compositions and processes for forming the initial transparent, conductive coating are described, for example, in (a) US 2011/0193032 and (b) US 2011/0124252. Accordingly, other embodiments are within the scope of the following claims.

What is claimed is:

1. A process for forming a transparent conductive coating on an elastomeric substrate comprising:
(a) providing an emulsion comprising metal nanoparticles dispersed in a liquid, where the liquid comprises (i) an oil phase comprising a solvent that is non-miscible with water and (ii) a water phase comprising water or a water-miscible solvent;
(b) applying the emulsion to a first substrate to form a wet coating;
(c) evaporating the liquid from the coating to form a dry coating comprising a network of electrically conductive metal traces that define cells that are transparent to light;
(d) depositing a curable elastomer precursor composition over the dry coating;
(e) curing the composition to form an elastomeric substrate having a sufficient thickness to be self-supporting; and
(f) separating the first substrate and elastomeric substrate to transfer the dry coating from the first substrate to the elastomeric substrate and form an article comprising a network of electrically conductive metal traces defining cells that are transparent to light on a self-supporting, elastomeric substrate.

2. The process of claim 1 wherein the cells are randomly shaped cells.

3. The process of claim 1 wherein the metal nanoparticles comprise silver nanoparticles.

4. The process of claim 1 wherein the emulsion comprises a water-in-oil emulsion.

5. The process of claim 1 wherein the emulsion comprises an oil-in-water emulsion.

6. The process of claim 1 wherein the elastomeric substrate has a thickness of at least 0.1 mm.

7. The process of claim 1 wherein the elastomeric substrate has a thickness ranging from 0.1 mm to 10 mm.

8. The process of claim 1 wherein the curable elastomeric precursor composition comprises a curable elastomeric silicone composition, and the elastomeric substrate comprises a silicone substrate.

9. The process of claim 8 wherein the silicone substrate comprises polydimethylsiloxane.

10. The process of claim 1 wherein the article exhibits a transmission of at least 80% to light in the wavelength range of 370 nm to 770 nm.

11. The process of claim 1 wherein the article exhibits a sheet resistance of no greater than 10 ohms/square.

12. The process of claim 1 further comprising sintering the dried coating prior to application of the curable elastomer precursor composition.

13. A transparent, conductive article comprising a network of electrically conductive metal traces defining cells that are transparent to light on a self-supporting, elastomeric substrate.

14. The article of claim 13 wherein the cells are randomly shaped cells.

15. The article of claim 13 wherein the metal traces comprise silver traces.

16. The article of claim 13 wherein the elastomeric substrate has a thickness of at least 0.1 mm.

17. The article of claim 13 wherein the elastomeric substrate has a thickness ranging from 0.1 mm to 10 mm.

18. The article of claim 13 wherein the elastomeric substrate comprises a silicone substrate.

19. The article of claim 18 wherein the silicone substrate comprises polydimethylsiloxane.

20. The article of claim 13 wherein the article exhibits a transmission of at least 80% to light in the wavelength range of 370 nm to 770 nm.

21. The article of claim 13 wherein the article exhibits a sheet resistance of no greater than 10 ohms/square.
